(19) United States
(12) Patent Application Publication
(10) Pub. No.: US 2026/0372134 A1
(43) Pub. Date: Nov. 19, 2026

(54) SEMICONDUCTOR DEVICE

(71) Applicant: Taiwan Semiconductor Manufacturing Company, Ltd., Hsinchu (TW)

(72) Inventors: Kai-Fang Cheng, Taoyuan City (TW); Hsiao-Kang Chang, Hsinchu City (TW)

(73) Assignee: Taiwan Semiconductor Manufacturing Company, Ltd., Hsinchu (TW)

(21) Appl. No.: 19/749,541

(22) Filed: Jul. 21, 2026

Related U.S. Application Data
(63) Continuation of application No. 18/391,546, filed on Dec. 20, 2023.

(51) Int. Cl. H10W 70/63; H10W 90/00; H10W 72/00; H10W 72/30; H10W 90/20

(52) U.S. Cl. CPC H10W 70/635; H10W 90/00; H10W 72/01361; H10W 72/01365; H10W 72/323; H10W 72/352; H10W 90/20; H10W 90/701; H10W 90/734

(57) ABSTRACT

A semiconductor device includes a first integrated circuit, a second integrated circuit and a bonding layer. The bonding layer is disposed between the first integrated circuit and the second integrated circuit, wherein the bonding layer includes a first layer and a second layer, the first layer is an aluminum nitride (AlN) layer, and the second layer is one of an aluminum oxide (AlO) layer and an aluminum oxynitride (AlON) layer.

### CROSS-REFERENCE TO RELATED APPLICATION

This application is a continuation application of and claims the priority benefit of a prior application serial No. 18/391,546, filed on Dec. 20, 2023. The entirety of the above-mentioned patent application is hereby incorporated by reference herein and made a part of this specification.

### BACKGROUND

The semiconductor integrated circuit (IC) industry has experienced a fast-paced growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component or line that can be created using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1G are schematic cross-sectional views illustrating a method of forming a semiconductor device according to some embodiments of the disclosure.

FIG. 2 is a schematic cross-sectional view of a semiconductor device according to some embodiments of the disclosure.

FIGS. 3A-3E are schematic cross-sectional views illustrating a method of forming a semiconductor device according to some embodiments of the disclosure.

FIGS. 4A and 4C are schematic cross-sectional views illustrating a method of forming a semiconductor device according to some embodiments of the disclosure.

FIG. 5 is a schematic cross-sectional view of a semiconductor device according to some embodiments of the disclosure.

FIG. 6 is a schematic cross-sectional view of a semiconductor device according to some embodiments of the disclosure.

FIG. 7 is a schematic cross-sectional view of a semiconductor device according to some embodiments of the disclosure.

FIG. 8 illustrates a flow chart of a method of forming a semiconductor device according to some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or features relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The present disclosure provides a thermal dissipation material to better dissipate heat from a semiconductor device. In some embodiments, the thermal dissipation material is a multilayer including an aluminum nitride layer and an aluminum oxide layer or an aluminum nitride layer and an aluminum oxynitride layer. The thermal dissipation material may function as a bonding layer for bonding integrated circuits, or function as a thermal dissipation pattern and/or an etch top layer for improving the thermal dissipation in the integrated circuit. By using the thermal dissipation material, the semiconductor device may have an improved thermal dissipation and thus improved yield and performance.

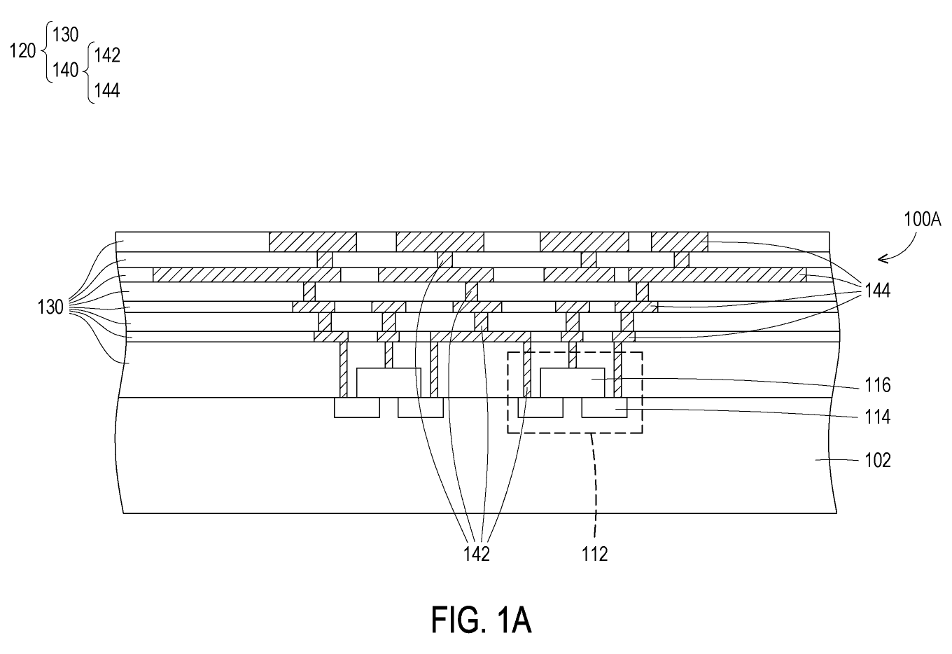

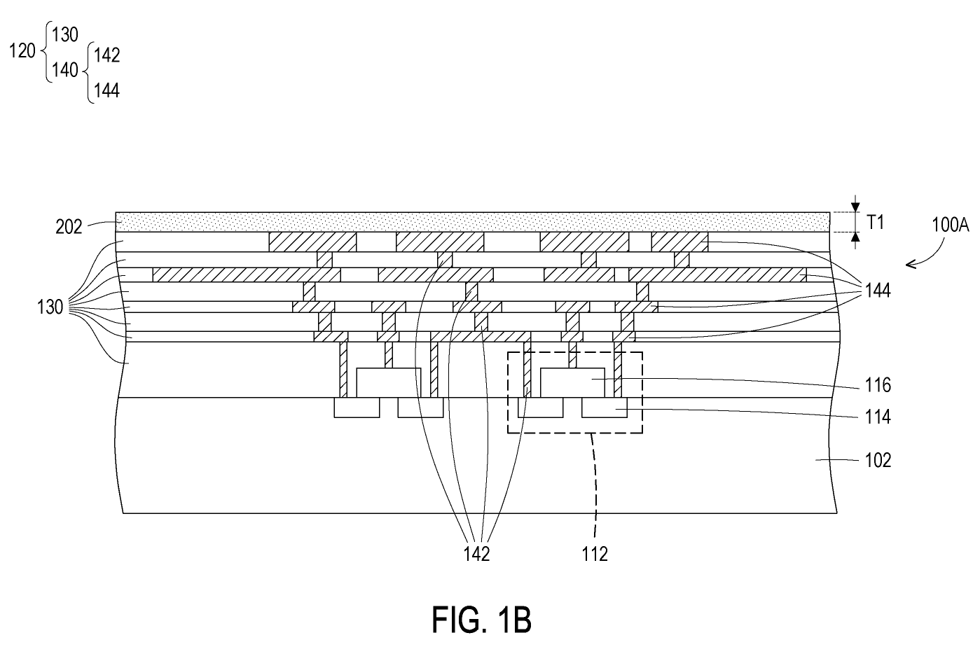

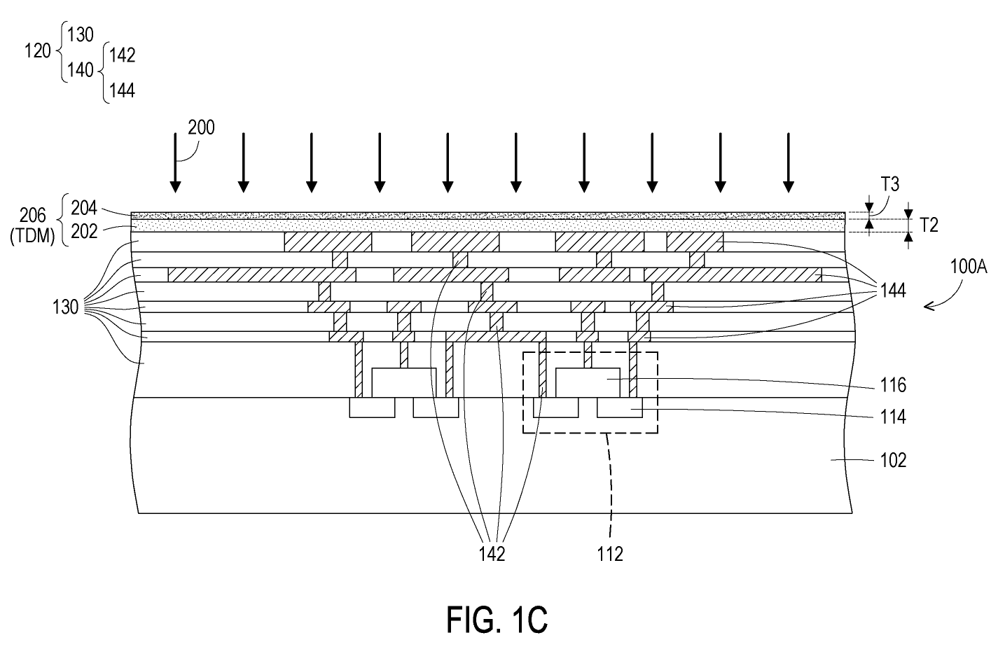

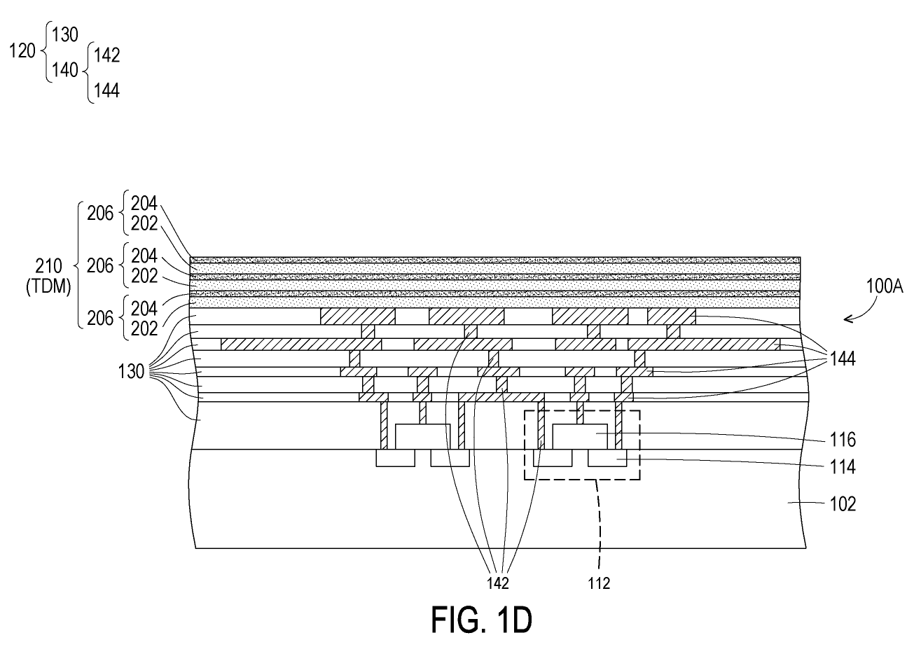

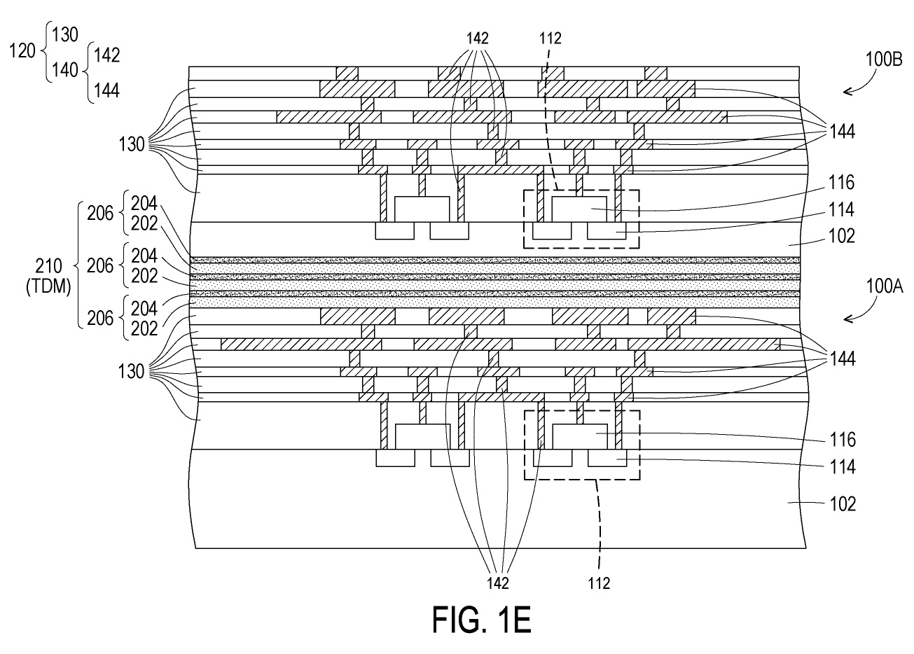

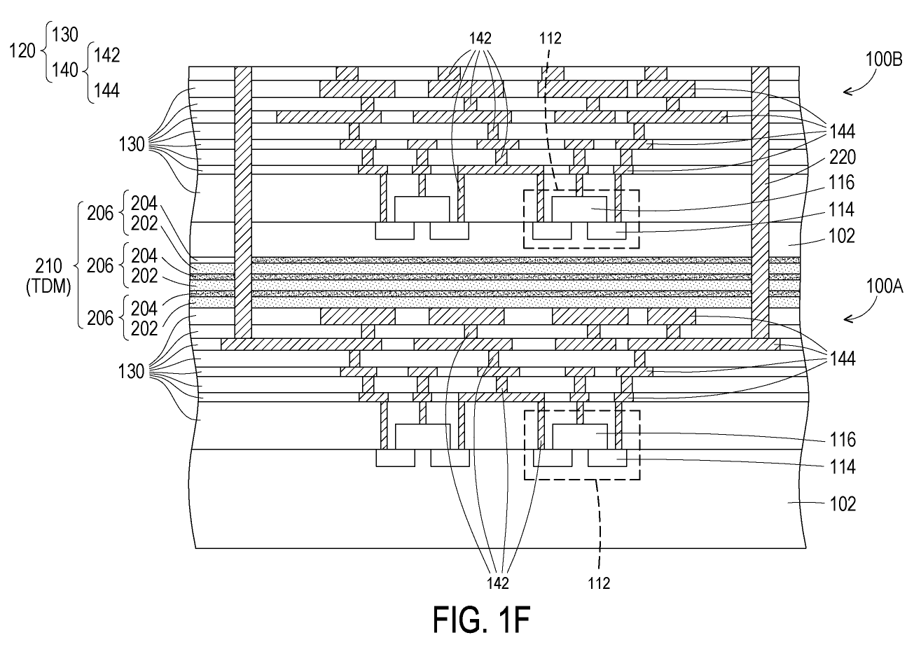

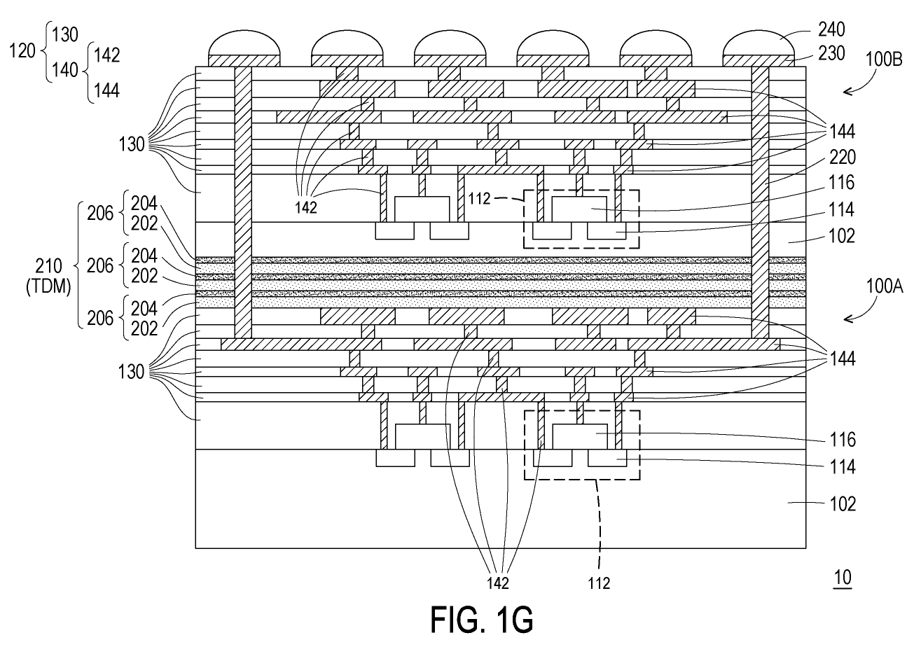

FIGS. 1A-1G are schematic cross-sectional views illustrating a method of forming a semiconductor device according to some embodiments of the disclosure.

Referring to FIG. 1A, an integrated circuit 100A is provided. The integrated circuit 100A may be a wafer, a die, a package, a die stack or the like, and the integrated circuit 100A may be also referred to as a circuit component. In some embodiments, the integrated circuit 100A include a semiconductor substrate 102, a plurality of devices 112 and an interconnect structure 120. In some embodiments, the semiconductor substrate 102 is made of elemental semiconductor materials, such as crystalline silicon, diamond, or germanium; compound semiconductor materials, such as silicon carbide, gallium arsenic, indium arsenide, or indium phosphide; or alloy semiconductor materials, such as silicon germanium, silicon germanium carbide, gallium arsenic phosphide, or gallium indium phosphide. The semiconductor substrate 102 may be a bulk silicon substrate, a silicon-on-insulator (SOI) substrate, or a germanium-on-insulator (GOI) substrate.

In some embodiments, the devices 112 are transistors. For example, each device 112 includes source/drain regions 114 and a gate electrode 116. Each device 112 may further include a channel region (not shown) under the gate electrode 116. The channel region may be also located between the source/drain regions 114 to serve as a path for electron to travel when the device 112 is turned on.

In some embodiments, the semiconductor substrate 102 includes various doped regions depending on circuit requirements (e.g., p-type semiconductor substrate or n-type semiconductor substrate). In some embodiments, the doped regions are doped with p-type or n-type dopants. For example, the doped regions may be doped with p-type dopants, such as boron or BF₂; n-type dopants, such as phosphorus or arsenic; and/or combinations thereof. In some embodiments, these doped regions serve as the source/drain regions 114 of the devices 112. Depending on the types of the dopants in the doped regions, the devices 112 may be referred to as n-type transistors or p-type transistors.

In some embodiments, the gate electrode 116 includes copper, titanium, tantalum, tungsten, aluminum, zirconium, hafnium, cobalt, titanium aluminum, tantalum aluminum, tungsten aluminum, zirconium aluminum, hafnium aluminum, titanium nitride, any other suitable metal-containing material, or a combination thereof. In some embodiments, the gate electrode 116 also includes materials to fine-tune the corresponding work function. For example, the gate electrode 116 may also include p-type work function materials such as Ru, Mo, WN, ZrSi₂, MoSi₂, TaSi₂, NiSi₂, or combinations thereof, or n-type work function materials such as Ag, TaCN, Mn, or combinations thereof.

In some embodiments, as shown in FIG. 1A, the source/drain regions 114 are embedded in the semiconductor substrate 102 and the gate electrode 116 is located above the semiconductor substrate 102. However, the disclosure is not limited thereto. In alternative embodiments, the source/drain regions 114 and the gate electrode 116 are both located above the semiconductor substrate 102. In some embodiments, the devices 112 may be separated by shallow trench isolation (STI; not shown) located between two adjacent devices 112. In some embodiments, the devices 112 are formed using suitable Front-end-of-line (FEOL) process.

The interconnect structure 120 is formed on the semiconductor substrate 102 and the devices 112. In some embodiments, the interconnect structure 120 includes a plurality of dielectric layers 130 and a plurality of conductive features 140. In some embodiments, the dielectric layers 130 are stacked on one another. For example, the adjacent dielectric layers 130 are in physical contact with each other. In some embodiments, a material of the dielectric layers 130 includes polyimide, epoxy resin, acrylic resin, phenol resin, benzocyclobutene (BCB), polybenzooxazole (PBO), or any other suitable polymer-based dielectric material. Alternatively, the dielectric layers 130 may be formed of oxides or nitrides, such as silicon oxide, silicon nitride, hafnium oxide, hafnium zirconium oxide, or the like. In some embodiments, different dielectric layers 130 are formed by the same material. However, the disclosure is not limited thereto. In alternative embodiments, different dielectric layers 130 may be formed by different materials. The dielectric layers 130 may be formed by suitable fabrication techniques, such as spin-on coating, chemical vapor deposition (CVD), plasma-enhanced chemical vapor deposition (PECVD), or the like. In some embodiments, a number of the dielectric layers 130 is eight, however, the number of the dielectric layers 130 may be less or more.

In some embodiments, the conductive features 140 include a plurality of conductive vias 142 and a plurality of conductive patterns 144. As illustrated in FIG. 1A, the conductive features 140 are embedded in the dielectric layers 130. That is, the conductive vias 142 and the conductive patterns 144 are embedded in the dielectric layers 130. For example, the dielectric layers 130 laterally encapsulate the conductive vias 142 and the conductive patterns 144. In some embodiments, the conductive patterns 144 extend horizontally. The conductive patterns 144 may be also referred to as conductive lines. Meanwhile, the conductive vias 142 extend vertically to connect the conductive patterns 144 located at different level heights. In other words, the conductive patterns 144 are electrically connected to one another through the conductive vias 142. In some embodiments, the bottommost conductive vias 142 are connected to the devices 112. For example, the bottommost conductive vias 142 are connected to the source/drain regions 114 and the gate electrodes 116 of the devices 112. In other words, the bottommost conductive vias 142 establish electrical connection between the devices 112 and the conductive patterns 144. That is, the conductive features 140 are electrically connected to the devices 112. In some embodiments, the bottommost conductive vias 142 may be referred to as “contact structures” of the devices 112.

In some embodiments, a material of the conductive patterns 144 and the conductive vias 142 includes copper, nickel, cobalt, ruthenium, iridium, aluminum, platinum, palladium, gold, silver, osmium, tungsten, molybdenum, titanium, the like or alloys thereof. The conductive patterns 144 and the conductive vias 142 may be formed by electrochemical plating (ECP) or deposition such as atomic layer deposition (ALD), chemical vapor deposition (CVD), physical vapor deposition (PVD) and electroless deposition (ELD), and/or photolithography and etching. In some embodiments, the process temperature for forming the conductive patterns 144 and the conductive vias 142 is 425° C or lower. In some embodiments, the conductive patterns 144 and the underlying conductive vias 142 are separately formed by a single damascene process. In some embodiments, as shown in FIG. 1A, the conductive vias 142 and the underlying conductive patterns 144 are respectively embedded in corresponding dielectric layers 130. However, the disclosure is not limited thereto. In alternative embodiments, the conductive patterns 144 and the underlying conductive vias 142 may be formed simultaneously by a dual damascene process. In such embodiments, the conductive vias 142 and the underlying conductive patterns 144 may be embedded in the same dielectric layer 130. In some embodiments, a top surface of each of the conductive via 142 and the conductive pattern 144 is coplanar with a top surface of the corresponding dielectric layer 130. In some embodiments, the topmost conductive features 140 are the conductive patterns 144. However, the disclosure is not limited thereto. In alternative embodiments, the topmost conductive features 140 are the conductive vias 142. Furthermore, the topmost conductive features 140 may be revealed or covered by the dielectric layer 130.

Referring to FIG. 1B, a first layer 202 is formed over the integrated circuit 100A. In some embodiments, the first layer 202 includes aluminum nitride (AlN). The first layer 202 may be deposited using physical vapor deposition (PVD). For example, the first layer 202 is deposited in a PVD chamber using an aluminum target and a flow of a nitrogen-containing gas, such as nitrogen (N₂). The PVD process for depositing the first layer 202 may be pulse DC sputtering or sputtering with a radio frequency (RF) biasing. In some embodiments, the first layer 202 is formed with high crystallinity in order for the first layer 202 to exhibit good thermal conductivity. However, in alternative embodiments, the first layer 202 may be crystalline, amorphous or a combination thereof according to the requirements. In order to have high crystallinity, the PVD process is performed at a low temperature, such as between about 20° C and about 300° C, and a low pressure, such as between about 1 Torr and about 3 Torr. The first layer 202 formed under the aforementioned conditions may have a thermal conductivity of between about 230 W/mK and about 320 W/mK at room temperature. In some embodiments, the first layer 202 may have a first thickness T1. In some embodiments, the first thickness T1 may be between about 100 Å and about 200 Å.

Referring to FIG. 1C, a treatment TT is performed to convert a top portion of the first layer 202 into a second layer 204. In some embodiments, the second layer 204 includes aluminum oxide (AlO) or aluminum oxynitride (AlON), which may be considered a partially oxidized form of the first layer 202 or an oxygen-doped form of the first layer 202. The second layer 204 may be also referred to as a leakage reduction layer. In one embodiment, the treatment TT includes a nitrous oxide (N₂O) plasma treatment. In this embodiment, the nitrous oxide (N₂O) plasma treatment introduces oxygen into the top portion of the first layer 202 and converts it into the second layer 204. In some embodiments, the nitrous oxide (N₂O) plasma treatment for forming aluminum oxide (AlO) or aluminum oxynitride (AlON) may include use of a dual frequency plasma source with a primary high frequency between about 500 W and about 1200 W and a secondary low frequency between about 50 W MHz and about 250 W. For example, the nitrous oxide plasma treatment lasts between about 5 seconds and about 60 seconds. In alternative embodiments, the nitrous oxide (N₂O) plasma treatment for forming aluminum oxynitride (AlON) may include use of a dual frequency plasma source with a primary high frequency between about 200 MHz and about 600 MHz and a secondary low frequency between about 50 MHz and about 300 MHz. For example, the nitrous oxide plasma treatment lasts between 1 and about 15 seconds. The nitrous oxide (N₂O) plasma treatment is performed at a low temperature, such as below 400° C. In alternative embodiments, the treatment TT includes an ultraviolet (UV) treatment in an ambient of an inert gas, such as argon (Ar), helium (He), or a combination of both (Ar/He). In such embodiments, the UV treatment may remove defects in the first layer 202. For example, the UV treatment lasts between about 6 seconds and about 60 seconds or between about 15 seconds and about 60 seconds, and frequency is between about 100 W and about 300 W. After the UV treatment, the treated first layer 202 is exposed to ambient air and the oxygen (O₂) in ambient air may be incorporated into the top portion of the first layer 202 to form the second layer 204. In alternative embodiments, the treatment TT may include both the UV treatment and the nitrous oxide (N₂O) plasma treatment. The former removes defects in the first layer 202 and the latter converts the top portion of the first layer 202 into a second layer 204. Compared to the first layer 202 that includes aluminum nitride (AlN), the second layer 204, which includes aluminum oxide (AlO) or aluminum oxynitride (AlON), exhibits a low electron leakage. The second layer 204 may be crystalline, amorphous or a combination thereof according to the requirements. The treatment TT may be regarded as an oxygen doping process and the oxygen doping impacts lattice thermal conductivity due to additional phonon-scattering. A second thickness T2 of the leftover first layer 202 (i.e., AlN layer) may be smaller, substantially the same as or larger than a third thickness T3 of the second layer 204 (i.e., AlO or AlON layer). In some embodiments, the initial thickness T1 may be between about 100 Å and about 200 Å, the second thickness T2 of the leftover first layer 202 (i.e., AlN layer) is between about 80 Å and about 160 Å, and the third thickness T3 of the second layer 204 (i.e., AlO or AlON layer) is between about 40 Å and about 70 Å. A difference thickness of the leftover first layer 202 (i.e., AlN layer) and the second layer 204 (i.e., AlO or AlON layer) is between about 40 Å and about 90 Å. However, the disclosure is not limited thereto. In some embodiments, the first layer 202 and the second layer 204 may be collectively referred to as a dielectric pair 206 or a composite dielectric layer.

Referring to FIG. 1D, after forming the dielectric pair 206, at least one additional dielectric pair 206 may be formed on the dielectric pair 206. In other words, the at least one additional dielectric pair 206 may be formed according to a desired total thickness of the thermal dissipation material TDM. For example, the formation of the first layer 202 in FIG. 1B and the second layer 204 in FIG. 1C may be repeated to form additional dielectric pairs 206. In this regard, it can be seen that operations in FIGS. 1B and 1C may be regarded as a cycle that can be repeated to reach the desired thickness. In some embodiments, the cycle that includes operations in FIGS. 1B and 1C may be performed once or repeated 1 to 100 times. The final stack of dielectric pairs 206 may be referred to as a thermal dissipation material TDM. That is, the thermal dissipation material TDM includes a plurality of first layers 202 interleaved by a plurality of second layers 204. For example, the thermal dissipation material TDM includes a plurality of AlN layers interleaved by a plurality of AlO layers, or the thermal dissipation material TDM includes a plurality of AlN layers interleaved by a plurality of AlON layers. When the cycle is only performed once, the thermal dissipation material TDM includes one first layer 202 and one second layer 204 and is one dielectric pair 206. For illustration purposes but not to limit the scope of the present disclosure, the thermal dissipation material TDM shown in FIG. 1D includes three (3) dielectric pairs 206. In alternative embodiments, the thermal dissipation material TDM may include less or more dielectric pairs 206 of first and second layers 202 and 204.

In some embodiments, the thermal dissipation material TDM is formed by performing the cycle of depositing the first layer 202 of FIG. 1B and converting a top portion of the first layer 202 into the second layer 204 of FIG. 1C once or repeatedly. However, the disclosure is not limited thereto. In some embodiments, the first layer 202 of AlN and the second layer 204 of AlO or AlON may be respectively deposited. The first layer 202 of AlN may be deposited using ALD or CVD. The deposition of the first layer 202 may include use of an aluminum-containing precursor and a nitrogen-containing precursor. Example aluminum-containing precursors may include trimethylaluminium (TMA) or triethylaluminium (TEA). Example nitrogen-containing precursors may include ammonia (NH₃), tertiarybutylamine (TBAm), or phenyl hydrazine. In some embodiments, the first layer 202 is possessed to have high crystallinity in order for the first layer 202 to exhibit good thermal conductivity. For example, the first layer 202 has a thermal conductivity of between about 230 W/mK and about 320 W/mK at room temperature. In some embodiments, the first layer 202 is deposited to have a desired thickness (e.g., the second thickness T2 as shown in FIG. 1C). The second layer 204 of AlO or AlON may be also deposited using ALD or CVD. When the second layer 204 includes aluminum oxide (AlO), the deposition may include an aluminum-containing precursor and an oxygen-containing precursor. Example aluminum-containing precursors may include trimethylaluminium (TMA) or triethylaluminium (TEA). Example oxygen-containing precursors may include oxygen (O₂) or nitrous oxide (N₂O). When the second layer 204 includes aluminum oxynitride (AlON), the deposition may include an aluminum-containing precursor, an oxygen-containing precursor, and a nitrogen-containing precursor. Example oxygen-containing precursors may include oxygen (O₂) or nitrous oxide (N₂O). Example aluminum-containing precursors may include trimethylaluminium (TMA) or triethylaluminium (TEA). Example nitrogen-containing precursors may include ammonia (NH₃), tertiarybutylamine (TBAm), or phenyl hydrazine. Since the depositions of the first layer 202 and the second layer 204 are both performed using ALD or CVD, the first layer 202 and the second layer 204 may be deposited in the same process chamber without breaking the vacuum. In some embodiments, the second layer 204 is deposited to have a desired thickness (e.g., the third thickness T3 as shown in FIG. 1C). The thickness of the first layer 202 (i.e., AlN layer) may be smaller, substantially the same as or larger than the thickness of the second layer 204 (i.e., AlO or AlON layer). In some embodiments, the thickness of the first layer 202 (i.e., AlN layer) is between about 80 Å and about 160 Å, and the thickness of the second layer 204 (i.e., AlO or AlON layer) is between about 40 Å and about 70 Å. A difference thickness of the first layer 202 (i.e., AlN layer) and the second layer 204 (i.e., AlO or AlON layer) is between about 40 Å and about 90 Å. However, the disclosure is not limited thereto. In such embodiments, the thermal dissipation material TDM is formed by performing the cycle of depositing the first layer 202 and depositing the second layer 204 once or repeatedly.

As mentioned above, the thermal dissipation material TDM exhibits good thermal conductivity and low electron leakage. In addition, the thermal dissipation material TDM further has adhesion property and thus may function as an adhesive. In some embodiments, the thermal dissipation material TDM serves as a bonding layer 210. In some embodiments, after the bonding layer 210 is formed on the integrated circuit 100A, a planarization process may be performed on the bonding layer 210. In some embodiments, the planarization process includes a mechanical grinding process, a CMP process, or the like. After the planarization process, the bonding layer 210 has a substantially flat top surface. It should be noted that the planarization process herein may be optional and may be omitted in certain embodiments.

Referring to FIG. 1E, after the bonding layer 210 is formed, an integrated circuit 100B is provided. In some embodiments, the integrated circuit 100B is similar to the integrated circuit 100A in FIG. 1A. In some embodiments, the integrated circuit 100B includes a semiconductor substrate 102, a plurality of devices 112 and an interconnect structure 120. Each of the devices 112 includes source/drain regions 114 and a gate electrode 116. The interconnect structure 120 includes a plurality of dielectric layers 130 and a plurality of conductive features 140, for example. The conductive features 140 may include a plurality of conductive vias 142 and a plurality of conductive patterns 144. In some embodiments, the topmost conductive feature 140 of the integrated circuit 100B is the conductive vias 142. In some embodiments, the semiconductor substrate 102, the devices 112, the source/drain regions 114, the gate electrode 116, the dielectric layers 130, the conductive vias 142 and the conductive patterns 144 in the integrated circuit 100B are respectively similar to those in the integrated circuit 100A, so the detailed descriptions thereof are omitted herein.

As illustrated in FIG. 1E, the integrated circuit 100B is placed on top of the integrated circuit 100A and is bonded to the integrated circuit 100A. In some embodiments, the integrated circuit 100B is attached to the integrated circuit 100A through the bonding layer 210. That is, the bonding layer 210 is sandwiched between the integrated circuit 100A and the integrated circuit 100B. As illustrated in FIG. 1E, the bonding layer 210 is in physical contact with both the dielectric layer 130 of the integrated circuit 100A and the semiconductor substrate 102 of the integrated circuit 100B.

In some embodiments, prior to the attachment of the integrated circuit 100B, the integrated circuit 100B may be placed on a carrier substrate (not shown). Thereafter, the semiconductor substrate 102 of the integrated circuit 100B may be thinned to reduce the overall thickness of the integrated circuit 100B. The thinning process includes a mechanical grinding process, a CMP process, or the like. After the semiconductor substrate 102 of the integrated circuit 100B is thinned, the integrated circuit 100B is placed on the bonding layer 210, so as to bond to the integrated circuit 100A. In some embodiments, the bonding between the integrated circuit 100A and the integrated circuit 100B is referred to a face-to-back bonding.

Referring to FIG. 1F, a plurality of through vias 220 is formed. In some embodiments, a material of the through vias 220 includes aluminum, titanium, copper, nickel, tungsten, or alloys thereof. The through vias 220 may be formed by electroplating, deposition, and/or photolithography and etching. As illustrated in FIG. 1F, the through vias 220 penetrate through the integrated circuit 100B, the bonding layer 210 and at least one of the dielectric layers 130 to be in physical contact with one of the conductive patterns 324. In other words, the through vias 220 is electrically connected to the interconnect structure 120 of the integrated circuit 100A.

Referring to FIG. 1G, a plurality of under-bump metallurgy (UBM) patterns 230 is formed on the conductive patterns 144 of the integrated circuit 100B and the through vias 220. For example, the UBM patterns 230 are formed on the topmost dielectric layer 130, the topmost conductive vias 142, and the through vias 220. In some embodiments, the UBM patterns 230 are in physical contact with the topmost conductive vias 142 to render electrical connection with the interconnect structure 120 of the integrated circuit 100B. Meanwhile, the UBM patterns 230 are also in physical contact with the through vias 220 to render electrical connection with the interconnect structure 120 of the integrated circuit 100A. In some embodiments, the UBM patterns 230 are formed by a sputtering process, a PVD process, a plating process, or the like. In some embodiments, the UBM patterns 230 are made of aluminum, titanium, copper, tungsten, and/or alloys thereof.

After the UBM patterns 230 are formed, a plurality of conductive terminals 240 is disposed on the UBM patterns 230. In some embodiments, the conductive terminals 240 are attached to the UBM patterns 230 through a solder flux. In some embodiments, the conductive terminals 240 are, for example, solder balls, ball grid array (BGA) balls, or controlled collapse chip connection (C4) bumps. In some embodiments, the conductive terminals 240 are made of a conductive material with low resistivity, such as Sn, Pb, Ag, Cu, Ni, Bi, or an alloy thereof.

Thereafter, a singulation process is performed on the interconnect structure 120 and the semiconductor substrate 102 of the integrated circuit 100B, the bonding layer 210, the interconnect structure 120, and the semiconductor substrate 102 of the integrated circuit 100A to obtain a plurality of semiconductor device 10. In some embodiments, the singulation process typically involves dicing with a rotation blade and/or a laser beam. In other words, the singulation process includes a laser cutting process, a mechanical cutting process, a laser grooving process, other suitable processes, or a combination thereof.

In some embodiments, the bonding layer including at least one pair of AlN layer and AlO layer or at least one pair of AlN layer and AlON layer functions as an adhesive layer for bonding the integrated circuits. In each pair, the AlN layer with high crystallinity may exhibit good thermal conductivity, and the AlO layer or AlON layer may exhibit a low electron leakage. For example, the breakdown field is higher than 3 MV/cm and the leakage current density as low as 10⁻⁷~10⁻⁹ A/cm². Thus, the bonding layer further provides a good thermal dissipation path for the semiconductor device including the bonded integrated circuits. Accordingly, the semiconductor device may have an improved thermal dissipation and thus improved yield and performance.

In some embodiments, the thermal dissipation material TDM serves as the bonding layer. However, the disclosure is not limited thereto. The thermal dissipation material TDM may be also used for forming a thermal dissipation pattern, an etch stop layer or the like.

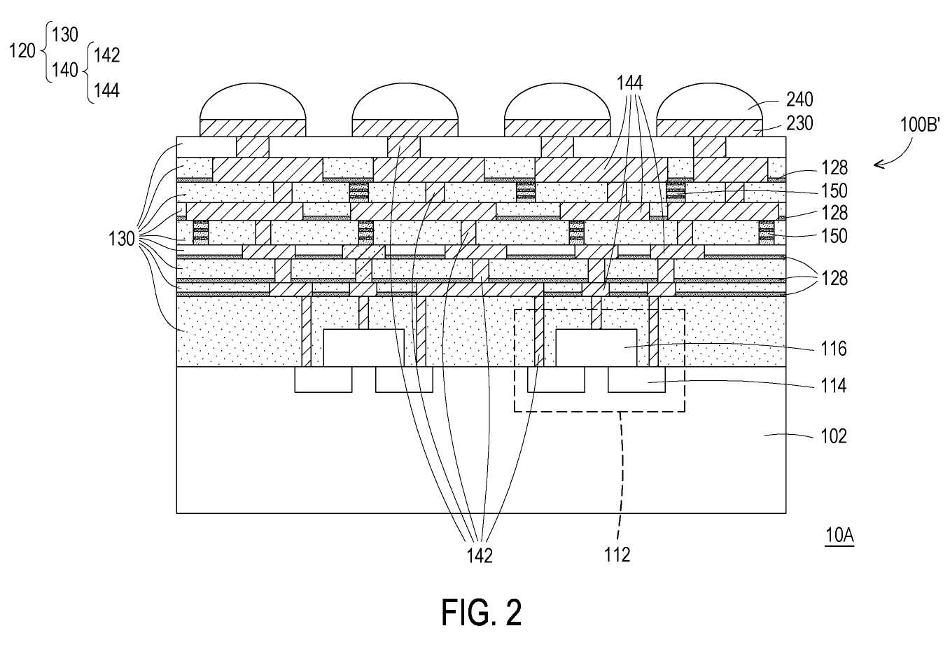

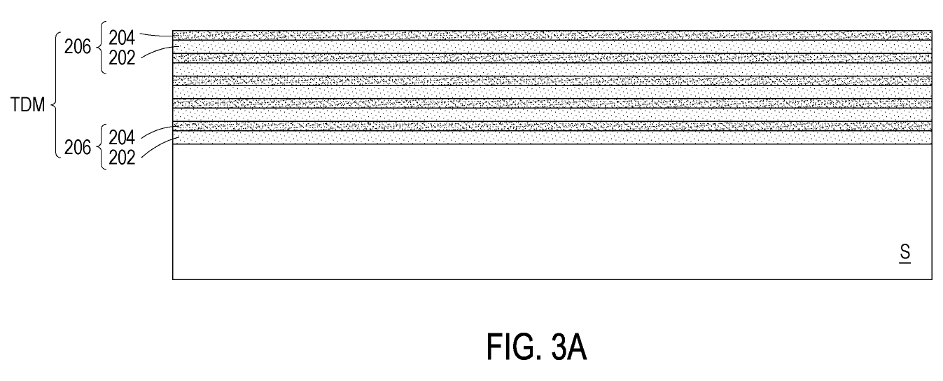

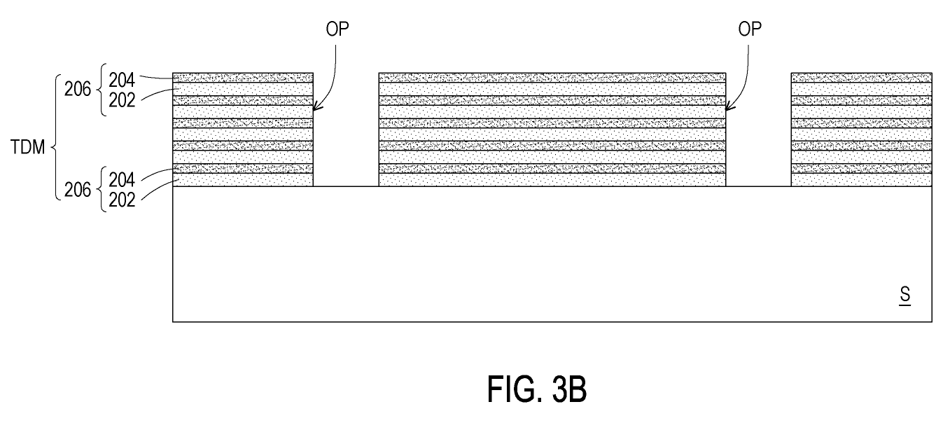

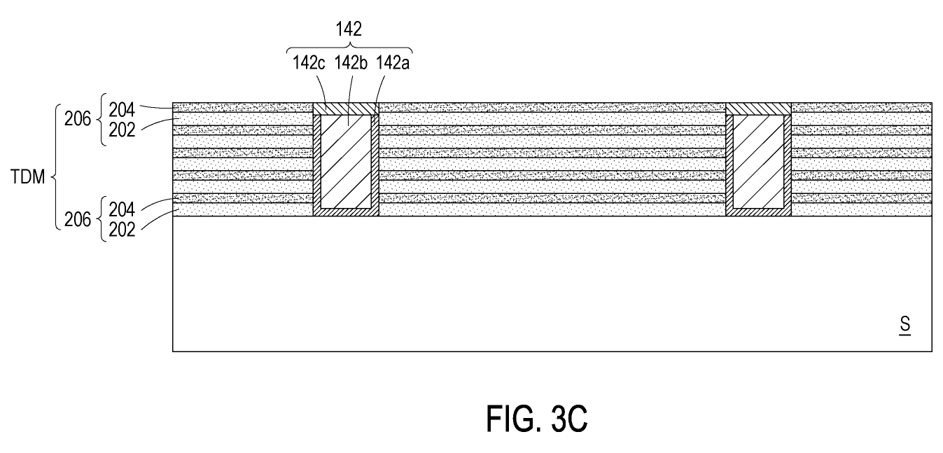

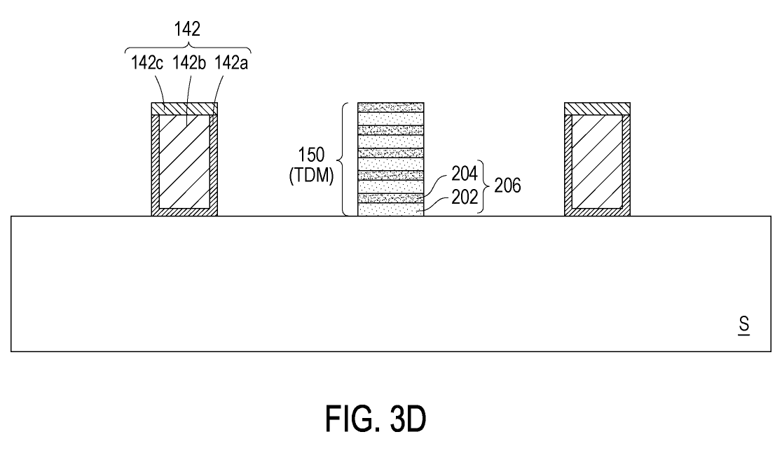

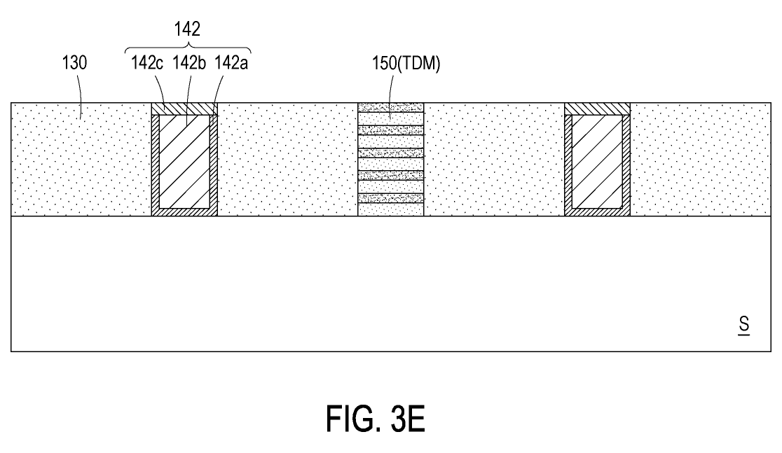

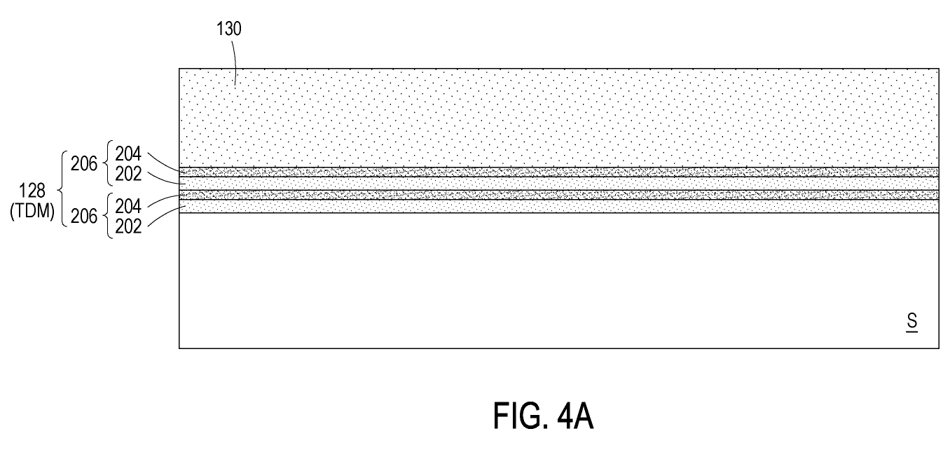

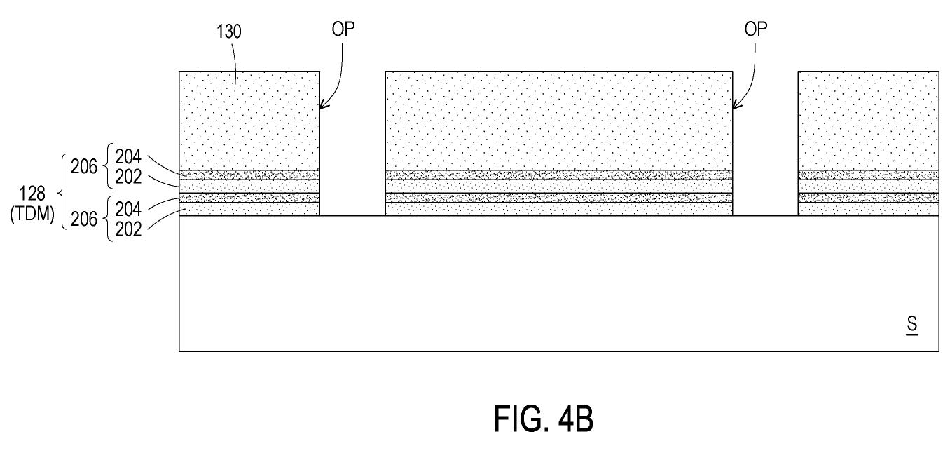

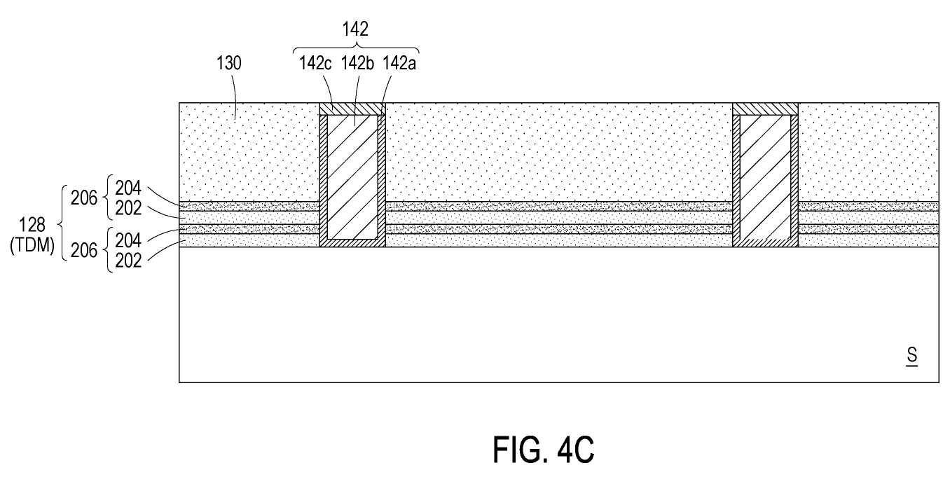

FIG. 2 is a schematic cross-sectional view of a semiconductor device according to some embodiments of the disclosure. In some embodiments, the semiconductor device 10A includes an integrated circuit 100B’ similar to the integrated circuit 100B shown in FIG. 1G, so similar elements are denoted by the same reference numeral and the detailed descriptions thereof are omitted herein. The difference between the integrated circuit 100B’ and the integrated circuit 100B lies in the formation of the interconnect structure 120 and a thermal dissipation pattern 150. In detail, in some embodiments, at least one layer of the interconnect structure 120 may adopt the method of FIGS. 3A-3E or 4A and 4C. It is noted that although the method of FIGS. 3A-3E or 4A and 4C is illustrated for forming the conductive vias 142, the method of FIGS. 3A-3E or 4A and 4C may be also used to form the conductive patterns 144.

FIGS. 3A-3E are schematic cross-sectional views illustrating a method of forming a semiconductor device (i.e., a layer of an interconnect structure) according to some embodiments of the disclosure.

Referring to FIG. 3A, a thermal dissipation material TDM is formed over a structure S. The structure S may be any dielectric layer 130 in the interconnect structure 120 or the semiconductor substrate 202 of FIG. 2. The thermal dissipation material TDM may be formed by performing the cycle of forming the first layer 202 and forming the second layer 204 once or repeatedly as mentioned above until a desired thickness of the thermal dissipation material TDM is achieved. The thickness of the thermal dissipation material TDM may be about the thickness of the dielectric layer 130 to be formed (shown in FIG. 3E). In some embodiments, the thermal dissipation material TDM includes a plurality of first layers 202 interleaved by a plurality of second layers 204. For example, the thermal dissipation material TDM includes a plurality of AlN layers interleaved by a plurality of AlO layers, or the thermal dissipation material TDM includes a plurality of AlN layers interleaved by a plurality of AlON layers. For illustration purposes but not to limit the scope of the present disclosure, the thermal dissipation material TDM includes five (5) dielectric pairs of first and second layers 202 and 204. In alternative embodiments, the thermal dissipation material TDM may include less or more dielectric pairs 206 of first and second layers 202 and 204.

Referring to FIG. 3B, the thermal dissipation material TDM is patterned to form a plurality of openings OP. For example, the openings OP penetrate through the thermal dissipation material TDM to partially expose the underlying conductive features 140 such as conductive patterns 144. In some embodiments, the patterning process of the thermal dissipation material TDM includes a photolithography process and an etching process. The etching process includes a dry etching process. For example, the thermal dissipation material TDM is patterned through RIE, ICP etch, ECR etch, NBE, or the like. In some embodiments, CF₄ or C₄F₈ is used as an etching gas during the dry etching process.

Referring to FIG. 3C, a plurality of conductive features 140 such as conductive vias 142 are formed in the openings OP. For example, a barrier material and a conductive material are conformally formed on the thermal dissipation material TDM. In some embodiments, the barrier material is conformally formed over exposed surfaces of the thermal dissipation material TDM (e.g., sidewall and bottom surfaces of the openings OP and top surfaces of the thermal dissipation material TDM) and the conductive material is conformally formed over the barrier material and fills up the openings OP. In some embodiments, the barrier material includes titanium nitride (TiN), tantalum nitride (TaN), titanium silicon nitride (TiSiN), tantalum silicon nitride (TaSiN), tungsten silicon nitride (WSiN), titanium carbide (TiC), tantalum carbide (TaC), titanium aluminum carbide (TiAlC), tantalum aluminum carbide (TaAlC), titanium aluminum nitride (TiAlN), tantalum aluminum nitride (TaAlN), a combination thereof or the like. In some embodiments, the barrier material is deposited over the thermal dissipation material TDM by CVD, PVD, or the like. In some embodiments, the conductive material includes aluminum, titanium, copper, nickel, tungsten, or alloys thereof. In some embodiments, the conductive material is deposited into the openings OP through PVD, ion beam deposition (IBD), CVD, ALD, molecular beam epitaxy (MBE), electro-chemical plating (ECP), electroless deposition (ELD), or the like. In some embodiments, the conductive material may be formed at a temperature lower than 425° C. Thereafter, a planarization process may be performed on the barrier material and the conductive material until the thermal dissipation material TDM is revealed. In some embodiments, the planarization process includes a mechanical grinding process, a CMP process, or the like. After the planarization process, top surfaces of the barrier material and the conductive material in the openings OP are exposed and coplanar with a top surface of the thermal dissipation material TDM. In some embodiments, a capping material is optionally formed on the exposed top surfaces of the barrier material and the conductive material after the planarization process. In some embodiments, the capping material includes cobalt, silicon nitride or the like, and the capping material is deposited through PVD, CVD, ALD, or the like at a temperature lower than 450° C. In some embodiments, as shown in FIG. 3C, the formed conductive via 142 includes a barrier layer 142a, a conductive layer 142b and a capping layer 142c. In some embodiments, the barrier layer 142a is disposed between the conductive layer 142b and the dielectric layer 130 and surrounds the conductive layer 142b. A top surface of the barrier layer 142a may be substantially coplanar with a top surface of the conductive layer 142b. The capping layer 142c is disposed on the top surface of the conductive layer 142b, and a top surface of the capping layer 142c is substantially coplanar with or higher than a top surface of the thermal dissipation material TDM, for example. In an embodiment in which the capping layer 142c is omitted, the top surfaces of the barrier layer 142a and the conductive layer 142b may be substantially coplanar with the top surface of the thermal dissipation material TDM.

Referring the FIG. 3D, after the conductive vias 142 are formed, the remained thermal dissipation material TDM is patterned, to form at least one thermal dissipation pattern 150. In some embodiments, the patterning process of the thermal dissipation material TDM includes a photolithography process and an etching process. The etching process includes a dry etching process. For example, the thermal dissipation material TDM may be patterned through RIE, ICP etch, ECR etch, NBE, or the like. In some embodiments, CF₄ or C₄F₈ may be used as an etching gas during the dry etching process. During the patterning process, the conductive vias 142 may be protected from being damaged such as masked by a mask. In some embodiments, as shown in FIG. 3D, the formed thermal dissipation pattern 150 includes a plurality of first layers 202 interleaved by a plurality of second layers 204. For example, the thermal dissipation material TDM includes a plurality of AlN layers interleaved by a plurality of AlO layers, or the thermal dissipation material TDM includes a plurality of AlN layers interleaved by a plurality of AlON layers. For illustration purposes but not to limit the scope of the present disclosure, the thermal dissipation pattern 150 shown in FIG. FIG. 3D includes five (5) dielectric pairs of first and second layers 202 and 204. The thermal dissipation pattern 150 may be disposed at any suitable location of the interconnect structure 120 of FIG. 2. For example, the thermal dissipation pattern 150 may be disposed in any dielectric layer 130 aside the conductive vias 142. In alternative embodiments, the thermal dissipation pattern 150 may be disposed in the dielectric layer 130 in which there is no conductive vias 142. Furthermore, the thermal dissipation pattern 150 may be disposed adjacent to the conductive patterns 144. In some embodiments, the thermal dissipation pattern 150 is formed as a via. However, the disclosure is not limited thereto. The thermal dissipation pattern 150 may have any suitable shape. For example, the thermal dissipation pattern 150 is line-shaped. In addition, there may be more than one thermal dissipation pattern 150 in a single dielectric layer 130. In some embodiments, the thermal dissipation pattern 150 only penetrates through one dielectric layer 130. However, the disclosure is not limited thereto. In alternative embodiments, the thermal dissipation pattern 150 continuously penetrates through at least two dielectric layers 130.

Referring the FIG. 3E, after the conductive features (e.g., conductive vias 142) and the thermal dissipation pattern 150 are formed, a dielectric layer 130 is formed to laterally encapsulate the conductive features (e.g., conductive vias 142) and the thermal dissipation pattern 150. In some embodiments, a material of the dielectric layer 130 includes boron carbo-nitride (BCN) based material, and the dielectric layer 130 is formed by suitable fabrication techniques, such as CVD, ALD, or the like. For example, the dielectric layer 130 is deposited in a CVD or ALD chamber using triethylamine borane with He, H₂ and NH₃. The deposition process may be performed at a low temperature, such as lower than 425° C. The K value of the formed dielectric layer 130 may be in a range between 1.9 to 2.8, and a hardness of the formed dielectric layer 130 may be in a range between 20 GPa to 30 GPa.

In alternative embodiments, a material of the dielectric layer 130 includes polyimide, epoxy resin, acrylic resin, phenol resin, benzocyclobutene (BCB), polybenzooxazole (PBO), or any other suitable polymer-based dielectric material. Alternatively, the dielectric layer 130 may be formed of oxides or nitrides, such as silicon oxide, silicon nitride, hafnium oxide, hafnium zirconium oxide, or the like. The dielectric layer 130 may be formed by suitable fabrication techniques, such as spin-on coating, chemical vapor deposition (CVD), plasma-enhanced chemical vapor deposition (PECVD), or the like.

In some embodiments, at least one of the dielectric layers 130 is formed of BCN based material. For example, in FIG. 2, some dielectric layers 130 are formed of BCN based material, and one or more dielectric layers 130 are formed of materials other than BCN based material. In alternative embodiments, all dielectric layers 130 are formed of BCN based material.

FIGS. 4A and 4C are schematic cross-sectional views illustrating a method of forming a semiconductor device (i.e., a layer of an interconnect structure) according to some embodiments of the disclosure.

Referring to FIG. 4A, an etch stop layer 128 is formed over a structure S, and a dielectric layer 130 is formed on the etch stop layer 128. The structure S may be any dielectric layer 130 in the interconnect structure 120 or the semiconductor substrate 202 of FIG. 2. In some embodiments, the etch stop layer 128 includes the thermal dissipation material TDM. In other words, the etch stop layer 128 may be formed by performing the cycle of forming the first layer 202 and forming the second layer 204 once or repeatedly until a desired thickness of the etch stop layer 128 is achieved. In such embodiments, as shown in FIG. 4A, the etch stop layer 128 includes a plurality of first layers 202 interleaved by a plurality of second layers 204. For example, the etch stop layer 128 includes a plurality of AlN layers interleaved by a plurality of AlO layers, or the etch stop layer 128 includes a plurality of AlN layers interleaved by a plurality of AlON layers. For illustration purposes but not to limit the scope of the present disclosure, the etch stop layer 128 shown in FIG. 4A includes two (2) dielectric pairs of first and second layers 202 and 204. However, the disclosure is not limited thereto. The etch stop layer 128 may include one (1) dielectric pair of first and second layers 202 and 204 or more than two (2) dielectric pairs of first and second layers 202 and 204. In some embodiments, as shown in FIG. 2, the etch stop layer 128 may be in direct contact with the underlying conductive features 140 such as conductive vias 142 and conductive patterns 144 and/or the underlying thermal dissipation pattern 150.

In alternative embodiments, a material of the etch stop layer 128 includes SiCN, AlN, AlON, AlO, AlOC, the like or a combination thereof, and the etch stop layer 128 is formed through CVD, ALD, or the like. For example, the etch stop layer 128 is formed of SiCₚN_{q}, and the etch stop layer 128 is formed by using Si(CH₃)₄ and NH₃ as target sources through CVD process or ALD process. Alternatively, the etch stop layer 128 is formed of AlNₓ, and the etch stop layer 128 is formed by using Al(CH₃)₃ and NH₃ as target sources through CVD process or ALD process. The etch stop layer 128 may include a single layer or a multilayer. However, the disclosure is not limited thereto.

In some embodiments, the dielectric layer 130 may be any one dielectric layer 130 in FIG. 2. In some embodiments, the dielectric layer 130 is formed on the etch stop layer 128 and in direct contact with the second layer 204 (e.g., AlO or AlON) of the etch stop layer 128. In some embodiments, a material of the dielectric layer 130 includes BCN based material, and the dielectric layer 130 is formed by suitable fabrication techniques, such as CVD, ALD, or the like. For example, the dielectric layer 130 is deposited in a CVD or ALD chamber using triethylamine borane with He, H₂ and NH₃. The deposition process may be performed at a low temperature, such as lower than 425° C. The K value of the formed dielectric layer 130 may be in a range between 1.9 to 2.8, and a hardness of the formed dielectric layer 130 may be in a range between 20 GPa to 30 GPa.

In alternative embodiments, a material of the dielectric layer 130 includes polyimide, epoxy resin, acrylic resin, phenol resin, benzocyclobutene (BCB), polybenzooxazole (PBO), or any other suitable polymer-based dielectric material. Alternatively, the dielectric layer 130 may be formed of oxides or nitrides, such as silicon oxide, silicon nitride, hafnium oxide, hafnium zirconium oxide, or the like. The dielectric layer 130 may be formed by suitable fabrication techniques, such as spin-on coating, chemical vapor deposition (CVD), plasma-enhanced chemical vapor deposition (PECVD), or the like.

Referring to FIG. 4B, the etch stop layer 128 and the dielectric layer 130 are patterned to form a plurality of openings OP. For example, the openings OP penetrate through the etch stop layer 128 and the dielectric layer 130 to partially expose the underlaying conductive features such as the conductive patterns 144, the conductive vias 142 the source/drain regions 114 and the gate electrode 116. In some embodiments, the patterning process of the etch stop layer 128 and the dielectric layer 130 includes a photolithography process and an etching process. The etching process includes a dry etching process. For example, the etch stop layer 128 and the dielectric layer 130 may be patterned through reactive ion etch (RIE), inductively coupled plasma (ICP) etch, electron cyclotron resonance (ECR) etch, neutral beam etch (NBE), or the like. In some embodiments, during the etching process of the dielectric layer 130, the etch stop layer 128 may prevent the over-etch, so as to protect the underlaying conductive features such as the conductive patterns 144, the conductive vias 142 the source/drain regions 114 and the gate electrode 116 from damaged.

Referring to FIG. 4C, a plurality of conductive features 140 such as conductive vias 142 are formed in the openings OP. For example, a barrier material and a conductive material are conformally formed on the dielectric layer 130. In some embodiments, the barrier material is conformally formed over exposed surfaces of the dielectric layer 130 (e.g., sidewall and bottom surfaces of the openings OP and top surfaces of the dielectric layer 130) and the conductive material is conformally formed over the barrier material and fills up the openings OP. In some embodiments, the barrier material includes titanium nitride (TiN), tantalum nitride (TaN), titanium silicon nitride (TiSiN), tantalum silicon nitride (TaSiN), tungsten silicon nitride (WSiN), titanium carbide (TiC), tantalum carbide (TaC), titanium aluminum carbide (TiAlC), tantalum aluminum carbide (TaAlC), titanium aluminum nitride (TiAlN), tantalum aluminum nitride (TaAlN), a combination thereof or the like. In some embodiments, the barrier material is deposited over the dielectric layer 130 by CVD, PVD, or the like. In some embodiments, the conductive material includes aluminum, titanium, copper, nickel, tungsten, or alloys thereof. In some embodiments, the conductive material is deposited into the openings OP through PVD, ion beam deposition (IBD), CVD, ALD, molecular beam epitaxy (MBE), electro-chemical plating (ECP), electroless deposition (ELD), or the like. In some embodiments, the conductive material may be formed at a temperature lower than 425° C. Thereafter, a planarization process may be performed on the barrier material and the conductive material until the dielectric layer 130 is revealed. In some embodiments, the planarization process includes a mechanical grinding process, a CMP process, or the like. After the planarization process, top surfaces of the barrier material and the conductive material in the openings OP are exposed and coplanar with a top surface of the dielectric layer 130. In some embodiments, a capping material is optionally formed on the exposed top surfaces of the barrier material and the conductive material after the planarization process. In some embodiments, the capping material includes cobalt, silicon nitride or the like, and the capping material is deposited through PVD, CVD, ALD, or the like at a temperature lower than 450° C. In some embodiments, as shown in FIG. 4C, the formed conductive via 142 includes a barrier layer 142a, a conductive layer 142b and a capping layer 142c. In some embodiments, the barrier layer 142a is disposed between the conductive layer 142b and the dielectric layer 130 and surrounds the conductive layer 142b. A top surface of the barrier layer 142a may be substantially coplanar with a top surface of the conductive layer 142b. The capping layer 142c is disposed on the top surface of the conductive layer 142b, and a top surface of the capping layer 142c is substantially coplanar with or higher than a top surface of the dielectric layer 130, for example. In an embodiment in which the capping layer 142c is omitted, the top surfaces of the barrier layer 142a and the conductive layer 142b may be substantially coplanar with the top surface of the dielectric layer 130.

As mentioned above, the thermal dissipation material exhibits good thermal conductivity and low electron leakage, and thus the etch stop layer 128 and the thermal dissipation pattern 150 may provide good thermal dissipation. In some embodiments, the etch stop layer 128 may be formed directly under each dielectric layer 130 of the interconnect structure 120 and in direct contact with the conductive features 140 and/or the thermal dissipation pattern(s) 150, the etch stop layer 128, the conductive features 140 and the thermal dissipation pattern(s) 150 may together form a good thermal dissipation path, so as to improve the thermal dissipation of the semiconductor device. In addition, by adopting the BCN based material as at least one of the dielectric layers of the interconnect structure, the dielectric layer has a low dielectric constant, a higher hardness and higher mechanical strength. Accordingly, the yield and/or the performance of the semiconductor device may be improved. Accordingly, the yield and/or the performance of the semiconductor device may be improved.

In some embodiments, the interconnect structure is considered as formed during back-end-of-line (BEOL) process. Generally, the thermal budget (i.e., the process temperature window) for BEOL process is low. As mentioned above, the process temperature for forming the thermal dissipation material is low, which falls within the thermal budget for BEOL process. In other words, the formation of the thermal dissipation pattern using the thermal dissipation material can be integrated into the process of the semiconductor device while being compatible with the BEOL thermal budget.

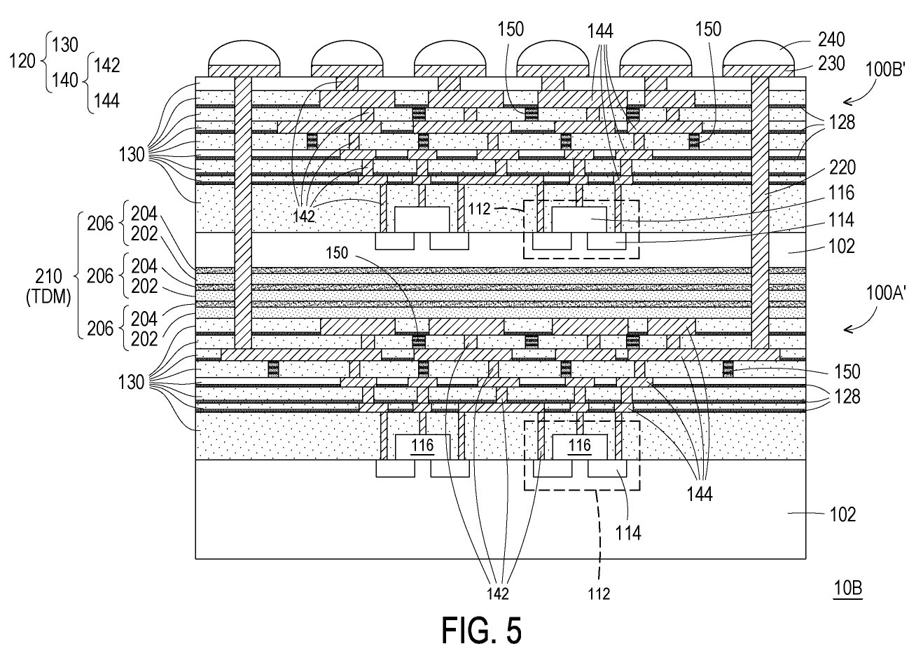

The integrated circuit 100B’ of FIG. 2 may be further stacked onto another integrated circuit. In some embodiments, as shown in FIG. 5, the integrated circuit 100B’ of FIG. 2 is bonded to an integrated circuit 100A’, to form a semiconductor device 10B. The integrated circuit 100A’ is similar to the integrated circuit 100A of FIG. 1G, and the difference lies in that the interconnect structure 120 of the integrated circuits 100A’ may be formed by using the method described in FIGS. 3A-3E and/or 4A-4C. In the semiconductor device 10B, at least one of the bonding layer 210, the etch stop layer 128 and the thermal dissipation pattern 150 may be formed of the thermal dissipation material TDM, and/or at least one of the dielectric layer 130 may be formed of the BCN based material.

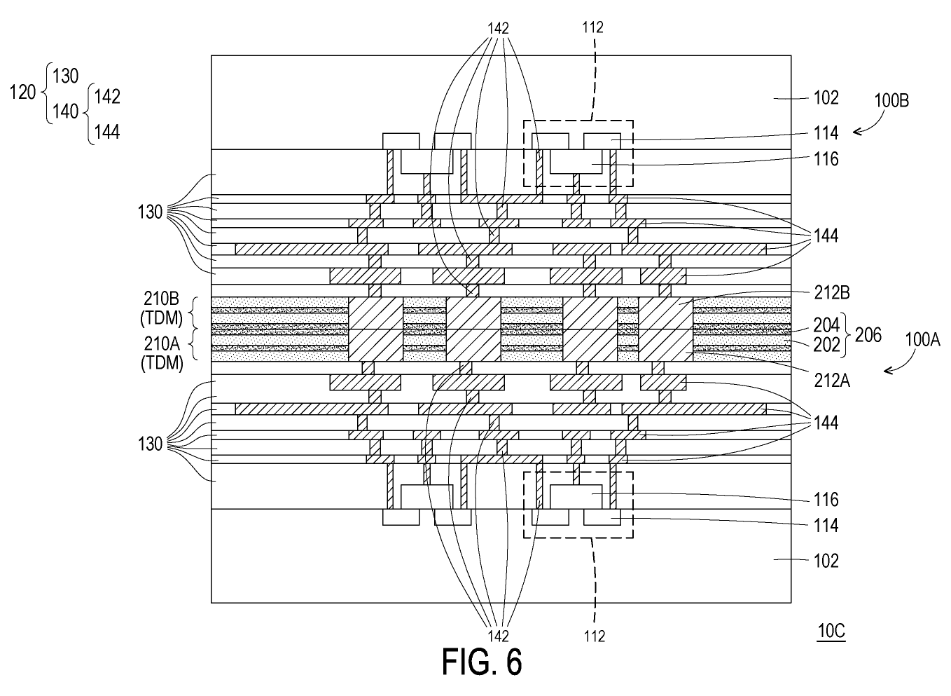

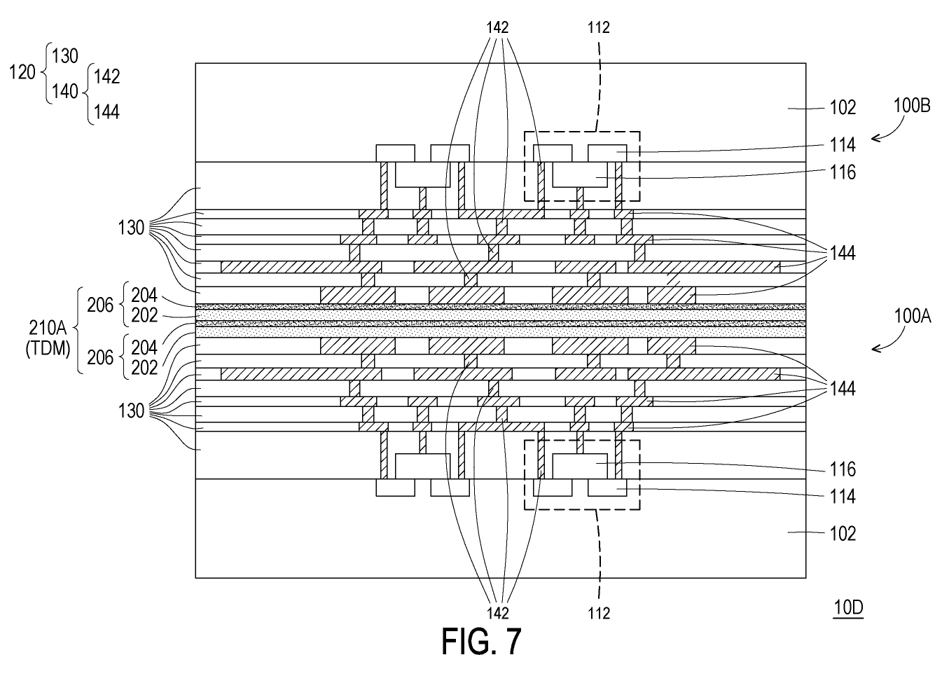

In the above embodiments, the integrated circuits are adhered and stacked. However, the disclosure is not limited thereto. In alternative embodiments, in a semiconductor device 10C, the integrated circuits 100A, 100B may be face-to-face bonded through the bonding layer 210. In such embodiments, the bonding layer 210 may be formed on at least one of the integrated circuits 100A, 100B. For example, as shown in FIG. 6, the bonding layer 210A is formed on the integrated circuits 100A, the bonding layer 210B is formed on the integrated circuits 100B and the bonding layers 210A and 210B are adhered to each other. The bonding layers 210A and 210B are similar to the bonding layer 210 of FIG. 1G, so the detailed descriptions thereof are omitted herein. In some embodiments, as shown in FIG. 6, bonding pads 212A and 212B in the bonding layers 210A and 210B may be bonded to each other. However, the disclosure is not limited thereto. In alternative embodiments, one of the bonding layers 210A and 210B may be omitted. As shown in FIG. 7, only the bonding layer 210A is disposed between the integrated circuits 100A, 100B. In alternative embodiments, the integrated circuits 100A may be similar to the integrated circuit 100A’, and/or the integrated circuits 100B may be similar to the integrated circuit 100B’, so as to improve the thermal dissipation.

In alternative embodiments, in the semiconductor device including the integrated circuit, at least one of the etch stop layer and the thermal dissipation pattern is formed of the thermal dissipation material TDM, and/or at least one of the dielectric layer is formed of the BCN based material. In alternative embodiments, in the semiconductor device including the bonded integrated circuits, at least one of the bonding layer, the etch stop layer and the thermal dissipation pattern is formed of the thermal dissipation material TDM, and/or at least one of the dielectric layer is formed of the BCN based material.

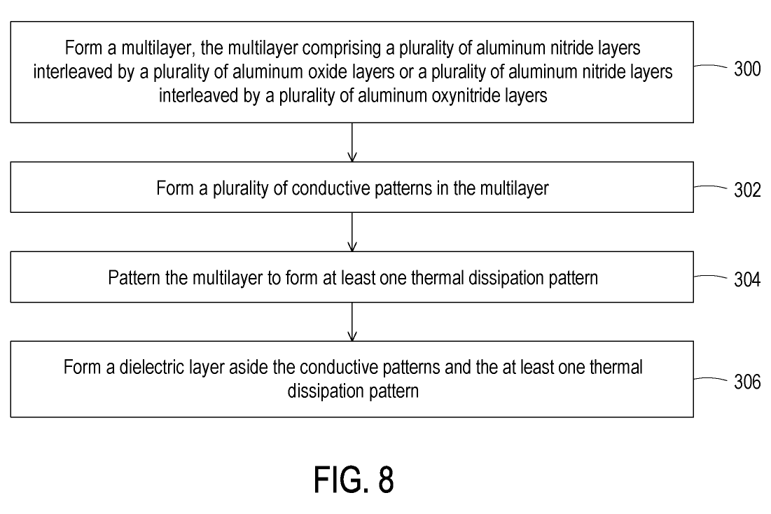

FIG. 8 illustrates a flow chart of a method of forming a semiconductor device according to some embodiments of the disclosure. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 300, a multilayer is formed, and the multilayer includes a plurality of aluminum nitride layers interleaved by a plurality of aluminum oxide layers or a plurality of aluminum nitride layers interleaved by a plurality of aluminum oxynitride layers. FIG. 3A illustrates a cross-sectional view corresponding to some embodiments of act 300.

At act 302, a plurality of conductive patterns are formed in the multilayer. FIG. 3C illustrates a cross-sectional view corresponding to some embodiments of act 302.

At act 304, the multilayer is patterned to form at least one thermal dissipation pattern. FIG. 3D illustrates a cross-sectional view corresponding to some embodiments of act 304.

At act 306, a dielectric layer is formed aside the conductive patterns and the at least one thermal dissipation pattern. FIG. 3E illustrates a cross-sectional view corresponding to some embodiments of act 306.

According to some embodiments of the disclosure, a semiconductor device includes a first integrated circuit, a second integrated circuit and a bonding layer. The bonding layer is disposed between the first integrated circuit and the second integrated circuit, wherein the bonding layer includes a first layer and a second layer, the first layer is an aluminum nitride (AlN) layer, and the second layer is one of an aluminum oxide (AlO) layer and an aluminum oxynitride (AlON) layer.

According to some embodiments of the disclosure, a semiconductor device includes an interconnect structure. The interconnect structure includes a plurality of dielectric layers, a plurality of conductive patterns and at least one thermal dissipation pattern. The at least one thermal dissipation pattern includes a first layer and a second layer, the first layer is an aluminum nitride (AlN) layer, and the second layer is one of an aluminum oxide (AlO) layer and an aluminum oxynitride (AlON) layer.

According to some embodiments of the disclosure, a method of forming a semiconductor device includes following steps. A multilayer is formed, and the multilayer includes a plurality of aluminum nitride layers interleaved by a plurality of aluminum oxide layers or a plurality of aluminum nitride layers interleaved by a plurality of aluminum oxynitride layers. A plurality of conductive patterns are formed in the multilayer. The multilayer is patterned to form at least one thermal dissipation pattern. A dielectric layer is formed aside the conductive patterns and the at least one thermal dissipation pattern.

According to some embodiments of the disclosure, a semiconductor device includes an interconnect structure. The interconnect structure includes a dielectric layer, at least one conductive pattern in the dielectric layer and at least one thermal dissipation pattern in the dielectric layer. The at least one thermal dissipation pattern includes a first layer and a second layer, the first layer is an aluminum nitride (AlN) layer, and the second layer is one of an aluminum oxide (AlO) layer and an aluminum oxynitride (AlON) layer.

According to some embodiments of the disclosure, a semiconductor device includes a first dielectric layer and a conductive pattern. The first dielectric layer includes a plurality of aluminum nitride layers interleaved by a plurality of aluminum oxide layers or a plurality of aluminum nitride layers interleaved by a plurality of aluminum oxynitride layers. The conductive pattern is disposed in the first dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first integrated circuit and a second integrated circuit; and
a bonding layer between the first integrated circuit and the second integrated circuit, wherein the bonding layer comprises a first layer and a second layer, the first layer is an aluminum nitride (AlN) layer, and the second layer is one of an aluminum oxide (AlO) layer and an aluminum oxynitride (AlON) layer.

2. The semiconductor device of claim 1, wherein a thickness difference between the first layer and the second layer is between about 40 Å and about 90 Å.

3. The semiconductor device of claim 1, wherein the first layer comprises a plurality of first layers, the second layer comprises a plurality of second layers, and the plurality of first layers are interleaved by the plurality of second layers.

4. The semiconductor device of claim 1, wherein the bonding layer interfaces with the first integrated circuit and the second integrated circuit.

5. The semiconductor device of claim 1, wherein the bonding layer interfaces with a dielectric layer of an interconnect structure of the first integrated circuit and a semiconductor substrate of the second integrated circuit.

6. The semiconductor device of claim 1, wherein the aluminum nitride (AlN) layer is a crystalline aluminum nitride (AlN) layer.

7. A semiconductor device, comprising:
an interconnect structure, comprising a dielectric layer, at least one conductive pattern in the dielectric layer and at least one thermal dissipation pattern in the dielectric layer, wherein
the at least one thermal dissipation pattern comprises a first layer and a second layer, the first layer is an aluminum nitride (AlN) layer, and the second layer is one of an aluminum oxide (AlO) layer and an aluminum oxynitride (AlON) layer.

8. The semiconductor device of claim 7, wherein the first layer interfaces with the second layer.

9. The semiconductor device of claim 7, wherein a material of the dielectric layer comprises boron carbo-nitride (BCN) based material.

10. The semiconductor device of claim 7, wherein the at least one thermal dissipation pattern comprises a plurality of the first layers interleaved by a plurality of the second layers.

11. The semiconductor device of claim 7, wherein the interconnect structure further comprises an etch stop layer beneath the dielectric layer, and the etch stop layer comprises the first layer and the second layer.

12. The semiconductor device of claim 11, wherein the at least one conductive pattern interfaces with the etch stop layer.

13. The semiconductor device of claim 11, wherein the at least one thermal dissipation pattern interfaces with the etch stop layer.

14. The semiconductor device of claim 11, wherein the etch stop layer comprises a plurality of the first layers interleaved by a plurality of the second layers.

15. The semiconductor device of claim 7, wherein the at least one conductive pattern comprises a plurality of conductive patterns, and the at least one thermal dissipation pattern is disposed between adjacent two of the plurality of conductive patterns.

16. The semiconductor device of claim 7, wherein the aluminum nitride (AlN) layer is a crystalline aluminum nitride (AlN) layer.

17. A semiconductor device, comprising:
a first dielectric layer, comprising a plurality of aluminum nitride layers interleaved by a plurality of aluminum oxide layers or a plurality of aluminum nitride layers interleaved by a plurality of aluminum oxynitride layers; and
a conductive pattern in the first dielectric layer.

18. The semiconductor device of claim 17, further comprising a second dielectric layer disposed on the first dielectric layer and having an etch selectivity different from the first dielectric layer, and the conductive pattern is further disposed in the second dielectric layer.

19. The semiconductor device of claim 17, further comprising a semiconductor substate on the first dielectric layer, wherein the conductive pattern penetrates through the semiconductor substate and the first dielectric layer.

20. The semiconductor device of claim 17, wherein a total height of the conductive pattern is substantially equal to or larger than a total thickness of the first dielectric layer .
